(19) United States
(12) Patent Application Publication
(10) Pub. No.: US 2024/0364303 A1
(43) Pub. Date: Oct. 31, 2024

(54) SURFACE ACOUSTIC WAVE FILTER FORMED ON SUBSTRATE WITH MULTI-LAYER STRUCTURE AND METHOD OF FABRICATING THE SAME

(71) Applicant: WISOL CO., LTD., Osan-si (KR)

(72) Inventors: Hun Yong LEE, Osan-si (KR); Tae Hyun KIM, Osan-si (KR); Yoshikazu KIHARA, Osan-si (KR)

(21) Appl. No.: 18/641,614

(22) Filed: Apr. 22, 2024

(30) Foreign Application Priority Data
Apr. 26, 2023 (KR) 10-2023- 0054513

(51) Int. Cl. H03H 9/02; H03H 3/08; H03H 9/25

(52) U.S. Cl. CPC H03H 9/02866; H03H 3/08; H03H 9/25

(57) ABSTRACT

A surface acoustic wave filter formed on a substrate with a multi-layer substrate and a method of fabricating the same are provided. The surface acoustic wave filter may include a support substrate; a high acoustic velocity layer formed on the support substrate; a low acoustic velocity layer formed on the high acoustic velocity layer; a piezoelectric layer formed on the low acoustic velocity layer; and a plurality of interdigital (IDT) electrodes formed on the piezoelectric layer, wherein the high acoustic velocity layer includes a first surface in contact with the support substrate and a second surface in contact with the low acoustic velocity layer, the low acoustic velocity layer includes a first surface in contact with the high acoustic velocity layer and a second surface in contact with the piezoelectric layer, and at least either one of the first and second surfaces of the high acoustic velocity layer, and the first and second surfaces of the low acoustic velocity layer is configured as a bonding surface.

### BACKGROUND OF THE INVENTION

### Field of the Invention

The present disclosure relates to a surface acoustic wave filter formed on a surface substrate with a multi-layer structure and a method of fabricating the same, and more particularly, to a surface acoustic wave filter forming a multi-layer structure of a substrate using a surface of a high acoustic velocity layer as a bonding surface and a method of fabricating the same.

### Background of the Related Art

A surface acoustic wave (SAW) refers to a wave propagating along a surface of an elastic solid, and such a surface acoustic wave propagates with energy concentrated near the surface, and corresponds to a mechanical wave. A surface acoustic wave device, which is an electromechanical device using an interaction between a surface acoustic wave and conduction electrons, uses the surface acoustic wave transmitted to a surface of a piezoelectric crystal. Such a surface acoustic wave device may have a very wide range of industrial applications, including sensors, oscillators, and filters, may achieve reduction in size and weight, and may have various advantages such as robustness, stability, sensitivity, low cost, and real-time performance.

In order to meet the requirements for high frequency and implement a surface acoustic wave filter with an improved Q value, a substrate having a structure in which a high acoustic velocity layer, a low acoustic velocity layer, and a piezoelectric layer are sequentially stacked on a support substrate is used. When processing a substrate having such a layer structure, a bonding structure as shown in FIGS. 1A to 1B has been proposed to prevent bending or cracking, especially in the piezoelectric layer.

Referring to FIG. 1A, a surface acoustic wave filter according to the related art includes a structure in which a first laminate having a high acoustic velocity layer 20 and a first low acoustic velocity layer 31 on a support substrate 10, and a second laminate having a second low acoustic velocity layer 32 formed on one surface of a piezoelectric material 40 are bonded through a medium of a bonding layer 60. In addition, referring to FIG. 1B, a surface acoustic wave filter according to the related art includes a structure in which a first laminate having a first high acoustic velocity layer 21 formed on a support substrate 10, and a second laminate including a low acoustic velocity layer 30 formed on one surface of the piezoelectric material 40, and a second high acoustic velocity layer 22 formed on one surface of the low acoustic velocity layer 30 are bonded to each other through a medium of a bonding layer 61.

In order to form such a bonding structure, in the case of FIG. 1A, chemical mechanical polishing (CMP) is performed once each on both bonding surfaces 33, 34 such that the bonding surface 33 of the first low acoustic velocity layer 31 and the bonding surface 34 of the second low acoustic velocity layer 32, which are to be bonded, have a roughness that allows bonding (e.g., a center line average roughness Ra is 0.5 nm or less), wherein a transmission electron microscopy (TEM) photo at this time is shown in FIG. 1C. In the case of FIG. 1B, as shown in FIG. 1A, CMP is performed on a bonding surface 23 of the first high acoustic velocity layer 21 and a bonding surface 24 of the second high acoustic velocity layer 22 to be bonded to each other through a medium of the bonding layer 61.

When forming a substrate using such a bonding method, at least two deposition processes, which are deposition processes for the first and second low acoustic velocity layers 21, 22, or deposition processes for the first and second high acoustic velocity layers 31, 32 are required, and the CMP process for the bonding surfaces 23, 24 or 33, 34 is also required twice each. In addition, the Q performance of the surface acoustic wave filter is adversely affected due to the creation of a parasitic conductance and the deterioration of the Q value due to the bonding layer 60, 61.

### SUMMARY OF THE INVENTION

Technical problems to be solved by the present disclosure are to provide a surface acoustic wave filter capable of eliminating an intervening bonding layer by using a surface of a high acoustic velocity layer as a bonding surface so as to achieve process simplification and prevent Q value deterioration, and a method of fabricating the same.

The technical problems of the present disclosure are not limited to the above-mentioned problems, and other technical problems which are not mentioned herein will be clearly understood by those skilled in the art from the description below.

In order to solve the foregoing technical problems, a surface acoustic wave filter formed on a substrate with a multi-layer structure according to some embodiments of the present disclosure may include a support substrate; a high acoustic velocity layer formed on the support substrate; a low acoustic velocity layer formed on the high acoustic velocity layer; a piezoelectric layer formed on the low acoustic velocity layer; and a plurality of interdigital (IDT) electrodes formed on the piezoelectric layer, wherein the high acoustic velocity layer includes a first surface in contact with the support substrate and a second surface in contact with the low acoustic velocity layer, and at least either one of the first and second surfaces of the high acoustic velocity layer is configured as a bonding surface.

In some embodiments of the present disclosure, the first surface of the high acoustic velocity layer may form a bonding surface with respect to the support substrate.

In some embodiments of the present disclosure, the first surface of the high acoustic velocity layer may be planarized by chemical mechanical planarization (CMP) or ion milling.

In some embodiments of the present disclosure, no bonding layer may be interposed between the first surface of the high acoustic velocity layer and the support substrate.

In some embodiments of the present disclosure, the first surface of the high acoustic velocity layer may have a surface roughness (Ra) of 0.5 nm or less.

In some embodiments of the present disclosure, the second surface of the high acoustic velocity layer may form a bonding surface with respect to the low acoustic velocity layer.

In some embodiments of the present disclosure, the second surface of the high acoustic velocity layer may be planarized by chemical mechanical planarization (CMP) or ion milling.

In order to solve the foregoing technical problems, a method of fabricating a surface acoustic wave filter formed on a substrate with a multi-layer structure according to some embodiments of the present disclosure may include sequentially forming a low acoustic velocity layer and a high acoustic velocity layer on a piezoelectric substrate; planarizing an upper surface of the high acoustic velocity layer; and bonding a support substrate to the high acoustic velocity layer through the upper surface of the high acoustic velocity layer.

In some embodiments of the present disclosure, the planarizing of a bonding surface of the high acoustic velocity layer may include performing CMP or ion milling on the bonding surface of the high acoustic velocity layer to have a surface roughness (Ra) of 0.5 nm or less.

In some embodiments of the present disclosure, the bonding of the support substrate to the high acoustic velocity layer through the upper surface of the high acoustic velocity layer may include bonding the support substrate to the high acoustic velocity layer through plasma-activated bonding or hydrophilic bonding.

In order to solve the foregoing technical problems a method of fabricating a surface acoustic wave filter formed on a substrate with a multi-layer structure according to some embodiments of the present disclosure may include forming a high acoustic velocity layer on a support substrate; forming a low acoustic velocity layer on a piezoelectric substrate; planarizing a bonding surface of the high acoustic velocity layer and a bonding surface of the low acoustic velocity layer; and bonding the high acoustic velocity layer to the low acoustic velocity layer.

In some embodiments of the present disclosure, the planarizing the bonding surface of the high acoustic velocity layer and the bonding surface of the low acoustic velocity layer may include performing CMP or ion milling on the bonding surface of the high acoustic velocity layer, and not performing a separate planarization process on the bonding surface of the low acoustic velocity layer by controlling deposition conditions in the forming of the low acoustic velocity layer.

Specific details of other embodiments are included in the detailed description and drawings.

According to a surface acoustic wave filter formed on a substrate with a multi-layer structure according to an embodiment of the present disclosure and a method of fabricating the same, a surface acoustic wave filter free from deterioration of a Q value may be obtained through a bonding structure having a support substrate and a high acoustic velocity layer without requiring a separate bonding layer.

In addition, the surface acoustic wave filter of the present disclosure may separate a bonding layer from a piezoelectric layer through which a surface acoustic wave propagates through a bonding between a support substrate and a high acoustic velocity layer, or a high acoustic velocity layer and a low acoustic velocity layer. Through this, scattering due to a disorder of a crystalline structure that may occur at a bonding surface during bonding may be prevented.

The effects of the present disclosure are not limited to the above-mentioned effects, and other effects that are not mentioned herein will be clearly understood by those skilled in the art from the description of the claims.

### BRIEF DESCRIPTION OF THE DRAWINGS

FIGS. 1A to 1D are diagrams for explaining a surface acoustic wave filter according to the related art and a method of fabricating the same.

FIG. 2 is a diagram for explaining a surface acoustic wave filter formed on a substrate with a multi-layer structure according to an embodiment of the present disclosure.

FIG. 3 is a diagram for explaining a bonding surface of the surface acoustic wave filter of FIG. 2.

FIG. 4 is a diagram for explaining a surface acoustic wave filter formed on a substrate with a multi-layer structure according to another embodiment of the present disclosure.

FIG. 5 is a diagram for explaining a bonding surface of the surface acoustic wave filter of FIG. 4.

FIGS. 6 to 9 are diagrams for explaining a method of fabricating a surface acoustic wave filter according to an embodiment of the present disclosure.

### DETAILED DESCRIPTION OF THE PREFERRED EMBODIMENT

Advantages and features of the present disclosure, and methods of accomplishing the same will be clearly understood with reference to the following embodiments described below in detail in conjunction with the accompanying drawings. However, the present disclosure is not limited to those embodiments disclosed below but may be implemented in various different forms. It should be noted that the present embodiments are merely provided to make a full disclosure of the invention and also to allow those skilled in the art to know the full range of the invention, and therefore, the present disclosure is to be defined only by the scope of the appended claims. Throughout the specification, the same reference numerals represent the same elements.

Designating that one element is “connected to” or “coupled to” other elements includes both a case where the element is directly connected or coupled to other elements and a case where other elements are interposed therebetween. On the contrary, designating that one element is “directly connected to” or “directly coupled to” other elements represents a case where other elements or layers are not interposed therebetween. In the specification, “and/or” includes respective mentioned items and all combinations of one or more items.

It should be noted that the terms used herein are merely used to describe the embodiments, but not to limit the present disclosure. In this specification, unless clearly used otherwise, expressions in a singular form include a plural form. The term “comprises” and/or “comprising” used in the specification intend to express an element, a step, an operation and/or a device does not exclude the existence or addition of one or more other elements, steps, operations and/or devices.

Although first, second, and the like are used to describe various elements, the elements are not, of course, limited to the terms. The terms are merely used to distinguish one element from other elements. Therefore, a first element mentioned below may also, of course, be a second element within the technical concept of the present disclosure.

Unless otherwise defined, all terms (including technical and scientific terms) used in this specification may be used with meanings that can be commonly understood by those skilled in the art to which the present disclosure pertains. Additionally, terms defined in commonly used dictionaries are not interpreted ideally or excessively unless clearly specifically defined.

FIG. 2 is a diagram for explaining a surface acoustic wave filter formed on a substrate with a multi-layer structure according to an embodiment of the present disclosure.

Referring to FIG. 2, a surface acoustic wave filter formed on a substrate with a multi-layer structure according to an embodiment of the present disclosure includes a support substrate 110, a high acoustic velocity layer 120, a low acoustic velocity layer 130, a piezoelectric layer 140, and an IDT electrode 150.

The support substrate 110 may include, for example, a silicon substrate, a sapphire substrate, an SiC substrate, a quartz substrate, a glass substrate, a LiTaO₃(LT) substrate, a LiNbO₃(LN) substrate, or the like.

A bonding surface 111 may be formed on one surface of the support substrate 110. When the support substrate 110 is mirror-processed, an additional CMP process on the bonding surface 111 may be unnecessary when bonding the high acoustic velocity layer 120.

The high acoustic velocity layer 120 may be bonded to the support substrate 110. The high acoustic velocity layer 120 is a layer that transmits an acoustic velocity higher than an acoustic wave propagating through the piezoelectric layer 140. In order to be bonded to the support substrate 110, a bonding surface 121 of the high acoustic velocity layer 120 may be CMP-processed or ion milled to have a polishing degree of 0.5 nm or less based on Ra. In another embodiment, Ra may be formed to be 0.5 nm or less by appropriately adjusting the deposition conditions of the high acoustic velocity layer 120.

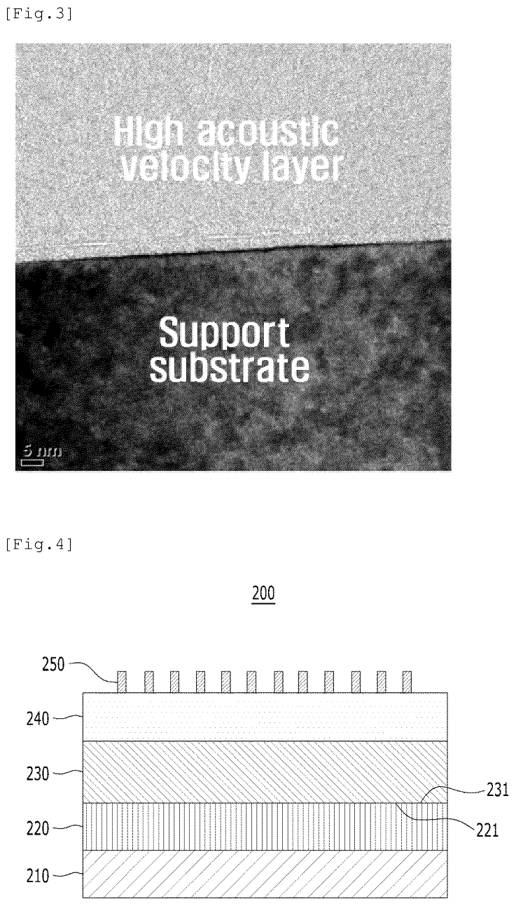

As can be seen in a TEM photo of a bonding surface between the support substrate 110 and the high acoustic velocity layer 120 in FIG. 3, the bonding surface 121 of the high acoustic velocity layer 120 may be formed to have a predetermined flatness.

The high acoustic velocity layer 120 may include, for example, amorphous silicon (a-Si), polysilicon (PolySi), silicon nitride (SiN), silicon oxynitride (SiON), aluminum nitride (AlN), boron nitride (BN), diamond, and the like.

A bonding between the high acoustic velocity layer 120 and the support substrate 110 may be performed, for example, by plasma-activated bonding, but is not limited thereto. For example, the high acoustic velocity layer 120 may be bonded to the bonding surface 111 of the support substrate 110 by hydrophilic bonding. In the case of such a bonding method, sufficient bonding strength may be obtained without using a bonding layer containing metal oxide.

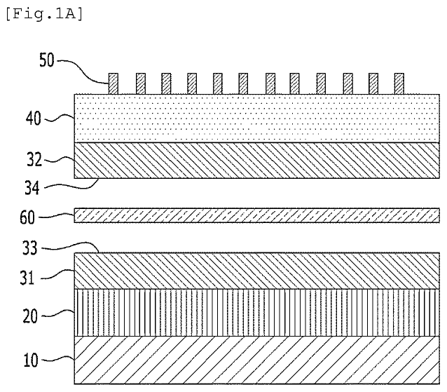

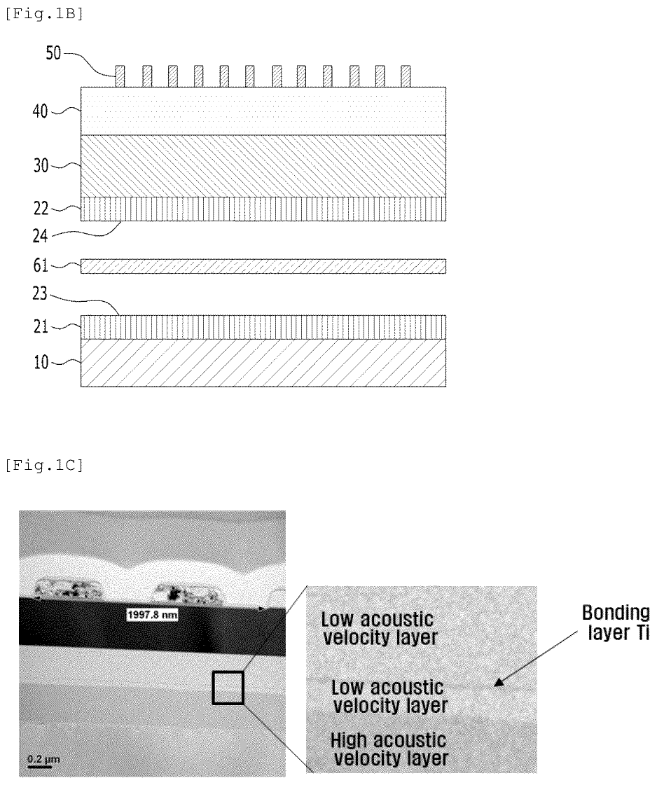

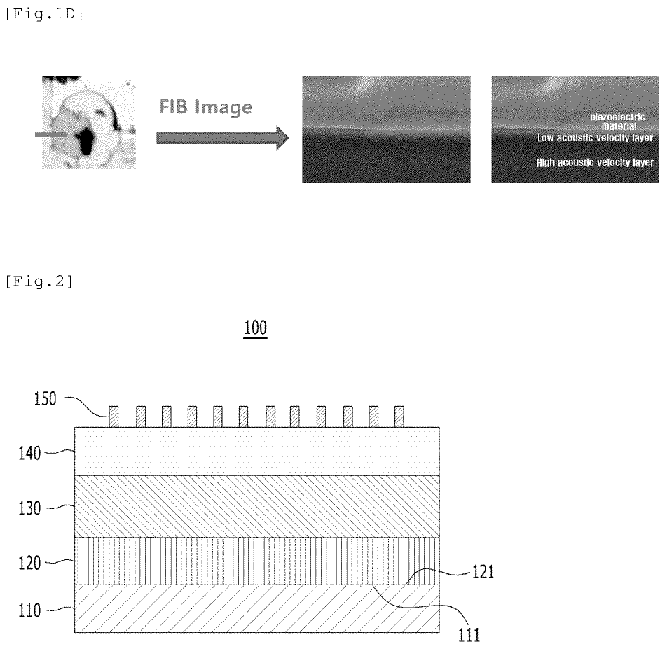

In a SAW filter 100 according to an embodiment of the present disclosure, it is required to perform a deposition on the low acoustic velocity layer 130 and the high acoustic velocity layer 120 once each so as to form a substrate structure through a bonding between the high acoustic velocity layer 120 and the support substrate 110, and it is required to perform CMP or ion milling once so as to form the bonding surface 121 of the high acoustic velocity layer 120. Compared to the case of FIGS. 1A and 1B, it is required to perform a deposition on the high acoustic velocity layer or the low acoustic velocity layer twice (a total of three times in consideration of the deposition of the remaining low acoustic velocity layer or high acoustic velocity layer), and it is required to perform CMP or ion milling on a bonding surface bonded to the bonding layer 60, 61 twice, and thus the fabrication process of the SAW filter 100 of the present disclosure may be further simplified.

Meanwhile, in some embodiments, when a surface roughness Ra of the high acoustic velocity layer 120 is formed to be 0.5 nm or less through controlling the deposition conditions, the fabrication process may be further simplified because additional processing such as CMP or ion milling is not required. Since there is no bonding layer, scattering of a surface acoustic wave generated by the bonding surface 121 may also be minimized.

In addition, the bonding layer 60, 61 of FIGS. 1A and 1B may include metal oxide or metal nitride, and does not become a complete insulator even when the post-oxidation process is carried out, so a parasitic conductance due to the metal properties of the bonding layers 60, 61 occurs to deteriorate a Q value of the SAW filter. On the contrary, a bonding structure between the support substrate 110 and the high acoustic velocity layer 120 in the SAW filter 100 of the present disclosure does not require a separate bonding layer, and thus may be free from deterioration of the Q value.

Finally, a substrate bonding structure of the SAW filter 100 in the present disclosure has an effect obtained by a bonding surface between the support substrate 110 and the high acoustic velocity layer 120 being far away from the piezoelectric layer 140. In the structure of the SAW filter 100 of the present disclosure, there is no bonding layer containing metal, metal oxide, or metal nitride, so a parasitic conductance does not occur, but there is some disorder of a crystalline structure in the vicinity of the bonding surface. The disorder of the crystalline structure may be an acoustic scattering factor for a surface acoustic wave. Therefore, it is preferable from the viewpoint of preventing Q value deterioration that the bonding surface is farther from the piezoelectric layer 140 than when it is adjacent to the piezoelectric layer 140, such as the piezoelectric layer 140 and the low acoustic velocity layer 130.

The low acoustic velocity layer 130 may be formed on the high acoustic velocity layer 120. As described above, since the SAW filter 100 of this embodiment has a laminated substrate structure through bonding the support substrate 110 to the high acoustic velocity layer 120, the low acoustic velocity layer 130 prior to bonding is located between the piezoelectric layer 140 and the high acoustic velocity layer 120.

An acoustic velocity of an acoustic wave propagating through the low acoustic velocity layer 130 is lower than that of an acoustic wave propagating through the piezoelectric layer 140. The low acoustic velocity layer 130 may include, for example, silicon oxide (SiO₂), silicon oxynitride, tellurium oxide (TeO₂), tantalum oxide (Ta₂O₅), and the like.

The piezoelectric layer 140 may include a piezoelectric element to generate an acoustic wave from a signal applied to the IDT electrode 150, and may include a material such as LiTaO₃ (LT), LiNbO₃ (LN) or the like.

A plurality of IDT electrodes 150 may be disposed on the piezoelectric layer 140. The IDT electrode 150 may correspond to a plurality of electrodes extending alternately from two bus bars extending to face each other on the piezoelectric layer 140. In the SAW filter 100, a velocity of the surface wave may be determined by a pitch, which is a distance between the IDT electrodes 150 adjacent to each other.

The IDT electrode 150 may be formed of at least one material selected from metal materials such as, for example, aluminum (Al), titanium (Ti), magnesium (Mg), zinc (Zn), cadmium (Cd), scandium (Sc), ruthenium (Ru), copper (Cu), silver (Ag), gold (Au), platinum (Pt), and tungsten (W).

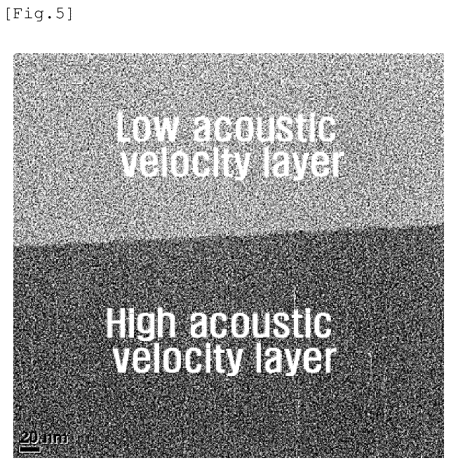

FIG. 4 is a diagram for explaining a surface acoustic wave filter formed on a substrate with a multi-layer structure according to another embodiment of the present disclosure. An element having a reference numeral similar to that of the foregoing embodiment may refer to an element similar to that of a previous embodiment.

Referring to FIG. 4, a surface acoustic wave filter 200 formed on a substrate with a multi-layer structure according to another embodiment of the present disclosure may have a bonding surface formed between a high acoustic velocity layer 220 and a low acoustic velocity layer 230. A TEM image of the bonding surface between the high acoustic velocity layer 220 and the low acoustic velocity layer 230 is shown in FIG. 5.

Specifically, the high acoustic velocity layer 220 formed on a support substrate 210 and the low acoustic velocity layer 230 formed on a piezoelectric layer 240 are bonded to each other through a method such as plasma-activated bonding or hydrophilic bonding. Prior to bonding, a planarization process such as CMP or ion milling may be performed on a bonding surface 221 of the high acoustic velocity layer 220 and a bonding surface 231 of the low acoustic velocity layer 230. In some embodiments of the present disclosure, the bonding surface 231 of the low acoustic velocity layer 230 may be formed to have a surface roughness that can be bonded (e.g., Ra<0.5 nm) through adjusting the deposition conditions, and thereby the planarization process may be omitted.

In the case of the SAW filter 200 in the embodiment of FIG. 4, it is required to perform a deposition on the high acoustic velocity layer 220 and the low acoustic velocity layer 230 once each, and to perform a polishing process on the bonding surface 221 of the high acoustic velocity layer 220 and the bonding surface 231 of the low acoustic velocity layer 230 once each so as to form a bonding structure. As described above, depending on the deposition conditions, the polishing process for the bonding surface 231 of the low acoustic velocity layer 230 may be omitted, and in this case, a simpler process is required compared to a series of processes for forming the structure of FIG. 1A or 1B.

In addition, unlike the process required by the bonding layer 60, 61 in FIG. 1A or 1B, only plasma-activated bonding or hydrophilic bonding may be required to bond the substrate structure of the SAW filter 200 of the present disclosure so as to thereby prevent Q value deterioration due to a metal component, and the bonding surface may be present between the high acoustic velocity layer 220 and the low acoustic velocity layer 230 rather than directly underneath the piezoelectric layer 240, and thus a certain degree of reduction in scattering of a surface acoustic wave may be expected.

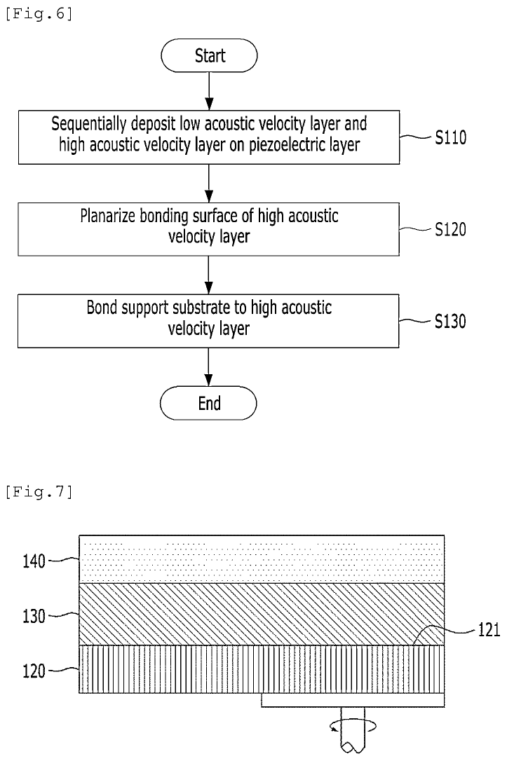

FIGS. 6 and 7 are diagrams for explaining a method of fabricating a surface acoustic wave filter formed on a substrate with a multi-layer structure according to an embodiment of the present disclosure.

First, referring to FIG. 6, a step S110 of sequentially depositing a low acoustic velocity layer and a high acoustic velocity layer on a piezoelectric layer is performed. For example, the low acoustic velocity layer 130 or the high acoustic velocity layer 120 may be formed on the piezoelectric layer 140 by growing using a method such as thermal oxidation or depositing using a method such as chemical vapor deposition (CVP) or sputtering.

Afterwards, referring to FIG. 7, a step S120 of planarizing the bonding surface 121 of the high acoustic velocity layer 120 may be performed. The bonding surface 121 of the high acoustic velocity layer 120 may be planarized through a process such as CMP or ion milling. The bonding surface 121 of the high acoustic velocity layer 120 may be planarized to have an Ra of 0.5 nm or less for bonding.

Finally, referring to FIG. 2, a step S130 of bonding the support substrate 110 to the high acoustic velocity layer 120 is performed. A bonding between the support substrate 110 and the high acoustic velocity layer 120 may be performed through, for example, plasma-activated bonding or hydrophilic bonding.

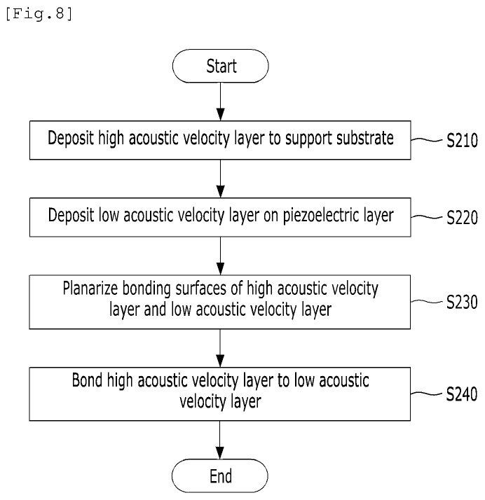

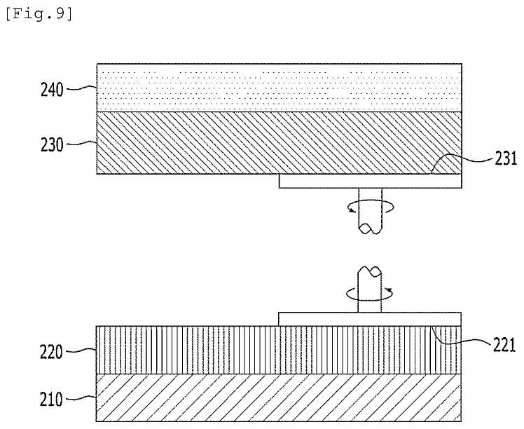

FIGS. 8 and 9 are diagrams for explaining a method of fabricating a surface acoustic wave filter formed on a substrate with a multi-layer structure according to another embodiment of the present disclosure.

First, referring to FIG. 8, a step S210 of forming a high acoustic velocity layer on a support substrate is performed. For example, the high acoustic velocity layer 220 may be formed on the support substrate 210 containing silicon by growing using a method such as thermal oxidation or by depositing using a method such as chemical vapor deposition (CVD) or sputtering.

Subsequently, a step S220 of forming a low acoustic velocity layer on a piezoelectric substrate is performed. In FIG. 8, the step 210 of forming a high acoustic velocity layer on a support substrate and the step of S220 of depositing a low acoustic velocity layer on a piezoelectric substrate do not have a sequential relationship, and the deposition step S220 of the low acoustic velocity layer may be performed first, and then the deposition step S210 of the high acoustic velocity layer may be performed. The low acoustic velocity layer 230 may be formed on the piezoelectric layer 240 made of a LT or LN material using a method such as CVD, PVD, or the like

Referring to FIG. 9, a step S120 of planarizing the bonding surface 221 of the high acoustic velocity layer 220 and the bonding surface 231 of the low acoustic velocity layer 230 may be performed. The bonding surfaces 221, 231 of the high acoustic velocity layer 220 and the low acoustic velocity layer 230 may be planarized through a process such as, for example, CMP, ion milling, or the like. In some embodiments of the present disclosure, the bonding surface 231 of the low acoustic velocity layer 230 may be formed to have a surface roughness that can be bonded (e.g., Ra<0.5 nm) through adjusting the deposition conditions or the like, and thereby the planarization process may be omitted.

Finally, referring to FIG. 4, a step S240 of bonding the high acoustic velocity layer 220 to the low acoustic velocity layer 230 is performed. A bonding between the high acoustic velocity layer 220 and the low acoustic velocity layer 230 may be performed through, for example, plasma-activated bonding or hydrophilic bonding.

As described above, the embodiments of the present disclosure have been described with reference to the accompanying drawings, but it will be apparent to those skilled in the art to which the invention pertains that the invention can be embodied in other specific forms without departing from the concept and essential characteristics thereof. Therefore, it should be understood that embodiments described above are merely illustrative but not restrictive in all aspects.

### DESCRIPTION OF SYMBOLS

100, 200, 300: SAW resonator
110, 210, 310: Support substrate
120, 220, 320: High acoustic velocity layer
130, 230, 330: Low acoustic velocity layer
140, 240, 340: Piezoelectric layer
150, 250, 350: IDT electrode

What is claimed is:

1. A surface acoustic wave filter formed on a substrate with a multi-layer structure, the surface acoustic wave filter comprising:
a support substrate;
a high acoustic velocity layer formed on the support substrate;
a low acoustic velocity layer formed on the high acoustic velocity layer;
a piezoelectric layer formed on the low acoustic velocity layer; and
a plurality of interdigital (IDT) electrodes formed on the piezoelectric layer,
wherein the high acoustic velocity layer comprises a first surface in contact with the support substrate and a second surface in contact with the low acoustic velocity layer, and
wherein at least either one of the first and second surfaces of the high acoustic velocity layer is configured as a bonding surface.

2. The surface acoustic wave filter of claim 1, wherein the first surface of the high acoustic velocity layer forms a bonding surface with respect to the support substrate.

3. The surface acoustic wave filter of claim 2, wherein the first surface of the high acoustic velocity layer is planarized by chemical mechanical planarization (CMP) or ion milling.

4. The surface acoustic wave filter of claim 2, wherein no bonding layer is interposed between the first surface of the high acoustic velocity layer and the support substrate.

5. The surface acoustic wave filter of claim 2, wherein the first surface of the high acoustic velocity layer has a surface roughness (Ra) of 0.5 nm or less.

6. The surface acoustic wave filter of claim 1, wherein the second surface of the high acoustic velocity layer forms a bonding surface with respect to the low acoustic velocity layer.

7. The surface acoustic wave filter of claim 6, wherein the second surface of the high acoustic velocity layer is planarized by chemical mechanical planarization (CMP) or ion milling.

8. A method of fabricating a surface acoustic wave filter formed on a substrate with a multi-layer structure, the method comprising:
sequentially forming a low acoustic velocity layer and a high acoustic velocity layer on a piezoelectric substrate;
planarizing an upper surface of the high acoustic velocity layer; and
bonding a support substrate to the high acoustic velocity layer through the upper surface of the high acoustic velocity layer.

9. The method of claim 8, wherein the planarizing of a bonding surface of the high acoustic velocity layer comprises:
performing CMP or ion milling on the bonding surface of the high acoustic velocity layer to have a surface roughness (Ra) of 0.5 nm or less.

10. The method of claim 9, wherein the bonding of the support substrate to the high acoustic velocity layer through the upper surface of the high acoustic velocity layer comprises:
bonding the support substrate to the high acoustic velocity layer through plasma-activated bonding or hydrophilic bonding.

11. A method of fabricating a surface acoustic wave filter formed on a substrate with a multi-layer structure, the method comprising:
forming a high acoustic velocity layer on a support substrate;
forming a low acoustic velocity layer on a piezoelectric substrate;
planarizing a bonding surface of the high acoustic velocity layer and a bonding surface of the low acoustic velocity layer; and
bonding the high acoustic velocity layer to the low acoustic velocity layer.

12. The method of claim 11, wherein the planarizing the bonding surface of the high acoustic velocity layer and the bonding surface of the low acoustic velocity layer comprises:
performing CMP or ion milling on the bonding surface of the high acoustic velocity layer, and not performing a separate planarization process on the bonding surface of the low acoustic velocity layer by controlling deposition conditions in the forming of the low acoustic velocity layer.
